(19) United States
(12) Patent Application Publication
(10) Pub. No.: US 2026/0096150 A1
(43) Pub. Date: Apr. 2, 2026

(54) TRANSISTOR, METHOD OF MANUFACTURING TRANSISTOR, AND ELECTRONIC DEVICE INCLUDING TRANSISTOR

(71) Applicants: Samsung Display Co., Ltd., Yongin-Si (KR); UIF (University Industry Foundation), Yonsei University, Seoul (KR)

(72) Inventors: Hyung Jun KIM, Yongin-si (KR); Sun Hee LEE, Yongin-si (KR); Hyung Jun KIM, Seoul (KR); Jeong Woo SEO, Goyang-si (KR); Hwi YOON, Seoul (KR); Seung Min CHUNG, Seoul (KR)

(21) Appl. No.: 19/242,049

(22) Filed: Jun. 18, 2025

(30) Foreign Application Priority Data
Sep. 30, 2024 (KR) 10-2024-0133050

(51) Int. Cl. H10D 30/67; H10D 30/01

(52) U.S. Cl. CPC H10D 30/674; H10D 30/031

(57) ABSTRACT

A transistor includes a gate electrode, a semiconductor layer located on the gate electrode, a gate insulating layer located between the gate electrode and the semiconductor layer, an electrode layer including a source electrode and a drain electrode spaced apart from each other on the semiconductor layer, and an intermediate layer located between the semiconductor layer and the electrode layer, and including interlayer patterns respectively overlapping the source electrode and the drain electrode.

This application claims priority to Korean Patent Application No. 10-2024-0133050, filed on Sep. 30, 2024, and all the benefits accruing therefrom under 35 U.S.C. § 119, the content of which in its entirety is herein incorporated by reference.

### BACKGROUND

### 1. Field

The disclosure relates to a display device. Specifically, the disclosure relates to a transistor included in the display device, a method of manufacturing the same, and an electronic device including the transistor.

### 2. Description of the Related Art

Recently, as interest in an information display has increased, research and development on a display device have been continuously conducted.

The content described above is only intended to help understanding of the background technology of the technical ideas of the disclosure, and therefore, it cannot be understood as a content corresponding to prior art known to those skilled in the art in the technical field of the disclosure.

### SUMMARY

An object to be solved by the disclosure is to provide a transistor having improved electron mobility.

An object to be solved by the disclosure is to provide a display device including the transistor having improved electron mobility.

An object to be solved by the disclosure is to provide a method of manufacturing the transistor having improved electron mobility.

Objects of the disclosure are not limited to the object described above, and other technical objects which are not described may be clearly understood by those skilled in the art from the description below.

According to embodiments of the disclosure, a transistor includes a gate electrode, a semiconductor layer disposed on the gate electrode, a gate insulating layer disposed between the gate electrode and the semiconductor layer, an electrode layer including a source electrode and a drain electrode spaced apart from each other on the semiconductor layer, and an intermediate layer disposed between the semiconductor layer and the electrode layer, and including interlayer patterns respectively overlapping the source electrode and the drain electrode.

In an embodiment, each of the semiconductor layer and the intermediate layer may include a material having a layered structure.

In an embodiment, each of the semiconductor layer and the intermediate layer may include transition metal dichalogenides (TMDC).

In an embodiment, the semiconductor layer may include molybdenum disulfide (MoS₂).

In an embodiment, the semiconductor layer may include one layer of molybdenum disulfide.

In an embodiment, the intermediate layer may include titanium disulfide (TiS₂).

In an embodiment, a thickness of the intermediate layer may be between about 9 nm and about 11 nm.

In an embodiment, the electrode layer may include a metal.

According to embodiments of the disclosure, a display device may include a substrate, a pixel circuit layer disposed on the substrate and including a transistor, and a display element layer disposed on the pixel circuit layer and including a light emitting element, and the transistor may include a gate electrode, a semiconductor layer disposed on the gate electrode, a gate insulating layer disposed between the gate electrode and the semiconductor layer, an electrode layer including a source electrode and a drain electrode spaced apart from each other on the semiconductor layer, and an intermediate layer disposed between the semiconductor layer and the electrode layer, and including interlayer patterns respectively overlapping the source electrode and the drain electrode.

In an embodiment, each of the semiconductor layer and the intermediate layer may include a material having a layered structure.

In an embodiment, each of the semiconductor layer and the intermediate layer may include transition metal dichalogenides (TMDC).

According to embodiments of the disclosure, a method of manufacturing a transistor may include forming a gate electrode, forming a gate insulating layer on the gate electrode, forming a semiconductor layer on the gate insulating layer, forming an intermediate layer including interlayer patterns spaced apart from each other and an electrode layer including a source electrode and a drain electrode spaced apart from each other and respectively overlapping the interlayer patterns on the semiconductor layer.

In an embodiment, the method may further include forming a photoresist pattern on the semiconductor layer after forming the semiconductor layer and before forming the intermediate layer.

In an embodiment, the forming the intermediate layer may be performed by atomic layer deposition (ALD).

In an embodiment, the forming the intermediate layer may include injecting a precursor into a surface of each of the semiconductor layer and the photoresist pattern, removing a precursor which is not adsorbed onto the surface of each of the semiconductor layer and the photoresist pattern, injecting a reactant into the surface of each of the semiconductor layer and the photoresist pattern, and removing the remaining reactant.

In an embodiment, the precursor may include tetrakis(dimethylamino)titanium (TDMAT).

In an embodiment, the reactant may include hydrogen sulfide (H₂S).

In an embodiment, the method may further include removing the photoresist pattern after forming the electrode layer, and in removing the photoresist pattern, a portion of each of the electrode layer and the intermediate layer overlapping the photoresist pattern may be removed to form the interlayer patterns spaced apart from each other and the source electrode and the drain electrode spaced apart from each other.

In an embodiment, the semiconductor layer may include molybdenum disulfide.

In an embodiment, the electrode layer may include metal.

An electronic device includes a processor to provide input image data; and a display device to display an image based on the input image data, wherein the display device includes: a gate electrode; a semiconductor layer disposed on the gate electrode; a gate insulating layer disposed between the gate electrode and the semiconductor layer; an electrode layer including a source electrode and a drain electrode spaced apart from each other on the semiconductor layer; and an intermediate layer disposed between the semiconductor layer and the electrode layer, and including interlayer patterns respectively overlapping the source electrode and the drain electrode.

Specific details of other embodiments are included in the detailed description and drawings.

According to the embodiment described above, by configuring the intermediate layer, which contacts with the semiconductor layer, with titanium disulfide and forming the intermediate layer by an atomic layer deposition process, a metal-induced gap states (MIGS) and a defect-induced gap state (DIGS) of the semiconductor layer may be suppressed. Accordingly, Fermi-level depinning may occur, and a contact resistance between the semiconductor layer and the intermediate layer may be reduced. As the contact resistance is reduced, electron mobility of a transistor may be improved.

Because each of the semiconductor layer and the intermediate layer includes a material having a layered structure and includes transition metal dichalogenides (TMDC), the semiconductor layer and the intermediate layer may include a material of a same series. That is, because compatibility of a material property of titanium disulfide and molybdenum disulfide is high, process compatibility between titanium disulfide and molybdenum disulfide may be secured. Accordingly, because the intermediate layer may be easily formed on the semiconductor layer, process efficiency may be improved.

An effect according to embodiments is not limited to the contents exemplified above, and more various effects are included in the present specification.

### BRIEF DESCRIPTION OF THE DRAWINGS

The above and other features of the disclosure will become more apparent by describing in further detail embodiments thereof with reference to the accompanying drawings, in which:

FIG. 1 is a block diagram illustrating an embodiment of a display device;

FIG. 2 is a block diagram illustrating an embodiment of one of sub-pixels of FIG. 1;

FIG. 3 is a plan view illustrating an embodiment of a display panel of FIG. 1;

FIG. 4 is a cross-sectional view illustrating an embodiment of the display panel of FIG. 3;

FIG. 5 is a cross-sectional view illustrating another embodiment of the display panel of FIG. 3;

FIG. 6 is a cross-sectional view illustrating an embodiment of a transistor included in a pixel circuit layer of FIG. 4 or 5;

FIG. 7 is an enlarged cross-sectional view of a portion of the semiconductor layer and the intermediate layer of FIG. 6;

FIG. 8 is a graph illustrating a transfer curve of the transistor shown in FIG. 6;

FIG. 9 is a graph illustrating a transfer curve of the transistor shown in FIG. 6;

FIGS. 10, 11, 12, 13, 14, 15, 16, 17, 18 and 19 are drawings illustrating an embodiment of a method of manufacturing the transistor of FIG. 6;

FIG. 20 is a block diagram of an electronic device according to an embodiment; and

FIG. 21 shows schematic views of various embodiments of an electronic device.

### DETAILED DESCRIPTION OF THE EMBODIMENT

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Similar reference numerals are used for similar components in describing each drawing. In the accompanying drawings, the dimensions of the structures are shown enlarged from the actual dimensions for the sake of clarity of the disclosure. Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. A case where a portion of a layer, a layer, an area, a plate, or the like is referred to as being “on” another portion, it includes not only a case where the portion is “directly on” another portion, but also a case where there is further another portion between the portion and another portion. In the present specification, in case that a portion of a layer, a layer, an area, a plate, or the like is formed on another portion, a forming direction is not limited to an upper direction but includes forming the portion on a side surface or in a lower direction. On the contrary, in case that a portion of a layer, a layer, an area, a plate, or the like is formed “under” another portion, this includes not only a case where the portion is “directly beneath” another portion but also a case where there is further another portion between the portion and another portion.

Hereinafter, preferred embodiments of the disclosure and others necessary for those skilled in the art to understand the disclosure will be described in detail with reference to the accompanying drawings. In the following description, the singular expressions include plural expressions unless the context clearly dictates otherwise.

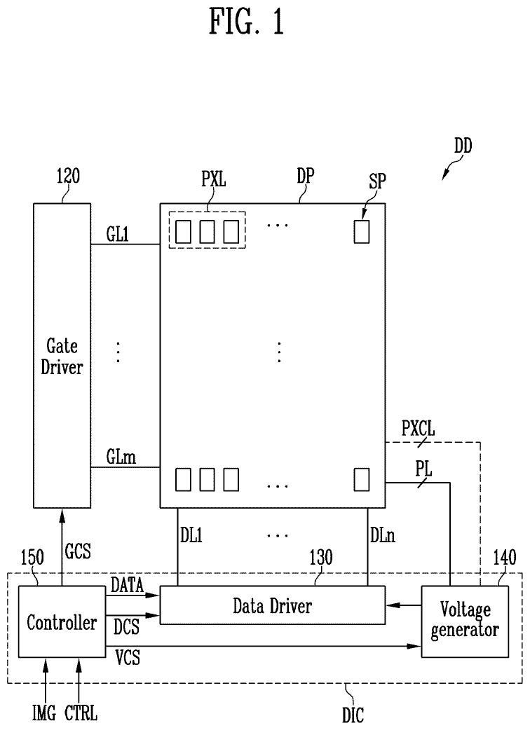

FIG. 1 is a block diagram illustrating an embodiment of a display device.

Referring to FIG. 1, the display device DD may include a display panel DP, a gate driver 120, a data driver 130, a voltage generator 140, and a controller 150.

The display panel DP includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, each of the sub-pixels SP may generate light such as red, green, blue, cyan, magenta, or yellow.

Two or more sub-pixels among the sub-pixels SP may constitute one pixel PXL. For example, the pixel PXL may include three sub-pixels as shown in FIG. 1. As described above, the pixel PXL may emit light of various colors and various luminances according to a combination of light emitted from the sub-pixels included in the pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal indicating a start of each frame, a horizontal synchronization signal, and the like.

The gate driver 120 may be located on one side of the display panel DP. However, embodiments are not limited thereto. For example, the gate driver 120 may include two or more physically and/or logically divided drivers, and such drivers may be located on one side of the display panel DP and another side of the display panel DP opposite the one side. As described above, the gate driver 120 may be located around the display panel DP in various shapes according to embodiments.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. In an embodiment, the data control signal DCS may include a source start signal, a source shift clock, a source output enable signal, and the like.

The data driver 130 may receive voltages from the voltage generator 140. The data driver 130 may apply data signals having grayscale voltages corresponding to the image data DATA to the first to n-th data lines DL1 to DLn using the received voltages. The data signals corresponding to the image data DATA may be applied to the data lines DL1 to DLn when the gate signal is applied to each of the first to m-th gate lines GL1 to GLm. Accordingly, the sub-pixels SP may generate light corresponding to the data signals, and the display panel DP may display an image.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to components of the display device DD, such as the gate driver 120, the data driver 130, and the controller 150. The voltage generator 140 may generate the plurality of voltages by receiving an input voltage from an outside of the display device DD and regulating the received voltage.

The voltage generator 140 may generate a first power voltage and a second power voltage. The generated first and second power voltages may be provided to the sub-pixels SP through power lines PL. In another embodiment, at least one of the first power voltage or the second power voltage may be provided from the outside of the display device DD.

In addition, the voltage generator 140 may provide various voltages and/or signals. For example, the voltage generator 140 may provide one or more initialization voltages applied to the sub-pixels SP. For example, during a sensing operation for sensing electrical characteristics of transistors and/or light emitting elements of the sub-pixels SP, a predetermined reference voltage may be applied to the first to n-th data lines DL1 to DLn, and the voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. In an embodiment, the voltage generator 140 may provide the pixel control signals to the sub-pixels SP through pixel control lines PXCL. In FIG. 1, the pixel control lines PXCL are connected between the voltage generator 140 and the display panel DP, but embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 controls overall operations of the display device DD. The controller 150 receives input image data IMG and a control signal CTRL corresponding thereto from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device DD or the display panel DP and output the image data DATA. In an embodiment, the controller 150 may output the image data DATA by aligning the input image data IMG so that the aligned input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In another embodiment, at least one of the data driver 130, the voltage generator 140, or the controller 150 may be provided as a component separated from the driver integrated circuit DIC.

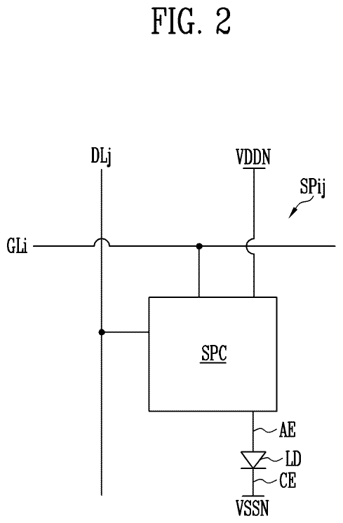

FIG. 2 is a block diagram illustrating an embodiment of one of the sub-pixels of FIG. 1. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD is connected between a first power voltage node VDDN and a second power voltage node VSSN. The first power voltage node VDDN is connected to one of the power lines PL of FIG. 1 and receive the first power voltage. The second power voltage node VSSN is connected to another one of the power lines PL of FIG. 1 and receive the second power voltage. The first power voltage may have a voltage level higher than that of the second power voltage.

The light emitting element LD is connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD is configured to emit light according to a current flowing from the anode electrode AE to the cathode electrode CE.

The sub-pixel circuit SPC may be connected to an i-th gate line GLi among the first to m-th gate lines GL1 to GLm of FIG. 1, and a j-th data line DLj among the first to n-th data lines DL1 to DLn of FIG. 1. In response to a gate signal received through the i-th gate line GLi, the sub-pixel circuit SPC controls the light emitting element LD to emit light according to a data signal received through the j-th data line DLj. In an embodiment, the sub-pixel circuit SPC may be further connected to the pixel control lines PXCL of FIG. 1. In this case, the sub-pixel circuit SPC may control the light emitting element LD in further response to the pixel control signals received through the pixel control lines PXCL.

For such operations, the sub-pixel circuit SPC may include pixel circuits, for example, transistors and one or more capacitors.

The transistors of the sub-pixel circuit SPC may include P-type transistors and/or N-type transistors. In an embodiment, the transistors of the sub-pixel circuit SPC may include a metal oxide silicon field effect transistor (MOSFET). In an embodiment, the transistors of the sub-pixel circuit SPC may include an amorphous silicon semiconductor, a monocrystalline silicon semiconductor, polycrystalline silicon semiconductor, an oxide semiconductor, and the like.

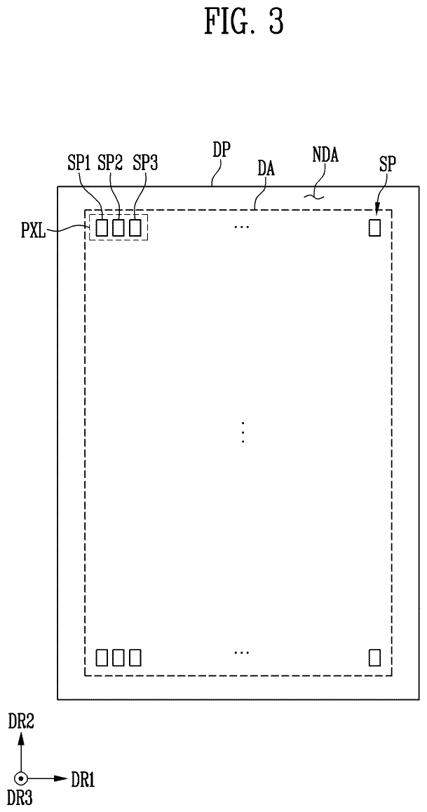

FIG. 3 is a plan view illustrating an embodiment of the display panel of FIG. 1.

Referring to FIG. 3, the display panel DP may include a display area DA and a non-display area NDA. The display panel DP displays an image through the display area DA. The non-display area NDA is located around the display area DA.

The display panel DP includes the sub-pixels SP in the display area DA. The sub-pixels SP may be arranged along a first direction DR1 and a second direction DR2 crossing the first direction DR1. For example, the sub-pixels SP may be arranged in a matrix form along the first direction DR1 and the second direction DR2. As another example, the sub-pixels SP may be arranged in a zigzag form along the first direction DR1 and the second direction DR2. An arrangement of the sub-pixels SP may vary according to embodiments. The first direction DR1 may be a row direction, and the second direction DR2 may be a column direction.

Two or more sub-pixels among the plurality of sub-pixels SP may constitute one pixel PXL. In FIG. 3, the pixel PXL includes three sub-pixels SP1 to SP3, but embodiments are not limited thereto. For example, the pixel PXL may include two sub-pixels. Hereinafter, for convenience of description, it is assumed that the pixel PXL includes the first to third sub-pixels SP1 to SP3.

Each of the first to third sub-pixels SP1 to SP3 may generate light of one of various colors such as red, green, blue, cyan, magenta, and yellow. Hereinafter, for clear and concise description, it is assumed that the first sub-pixel SP1 is configured to generate light of a red color, the second sub-pixel SP2 is configured to generate light of a green color, and the third sub-pixel SP3 is configured to generate light of a blue color.

Each of the first to third sub-pixels SP1 to SP3 may include at least one light emitting element configured to generate light. In embodiments, the light emitting elements of the first to third sub-pixels SP1 to SP3 may generate light of a same color. For example, the light emitting elements of the first to third sub-pixels SP1 to SP3 may generate the light of the blue color. In other embodiments, the light emitting elements of the first to third sub-pixels SP1 to SP3 may generate light of different colors. For example, the light emitting elements of the first to third sub-pixels SP1 to SP3 may generate the light of the red color, the green color, and the blue color, respectively.

As the display panel DP, a display panel capable of self-emission, such as a light emitting diode display panel (LED display panel) using a micro scale or nano scale of light emitting diode as the light emitting element, an organic light emitting display panel (OLED panel) using an organic light emitting diode as the light emitting element, or the like, may be used.

A component for controlling the sub-pixels SP may be located in the non-display area NDA. Lines connected to the sub-pixels SP, for example, the first to m-th gate lines GL1 to GLm of FIG. 1, the first to n-th data lines DL1 to DLn, the power lines PL, and the pixel control lines PXCL may be located in the non-display area NDA.

At least one of the gate driver 120, the data driver 130, the voltage generator 140, or the controller 150 of FIG. 1 may be located in the non-display area NDA of the display panel DP. In embodiments, the gate driver 120 may be located in the non-display area NDA. In this case, the data driver 130, the voltage generator 140, and the controller 150 may be implemented as a driver integrated circuit DIC of FIG. 1 which is separate from the display panel DP and the driver integrated circuit DIC may be connected to the lines located in the non-display area NDA. In other embodiments, the gate driver 120 may be implemented as one integrated circuit separate from the display panel DP together with the data driver 130, the voltage generator 140, and the controller 150.

In embodiments, the display area DA may have various shapes. The display area DA may have a closed loop shape including sides of a straight line and/or a curved line. For example, the display area DA may have shapes of a polygon, a circle, a semicircle, an ellipse, and the like.

In embodiments, the display panel DP may have a flat display surface. In other embodiments, the display panel DP may have a display surface which is at least partially round. In embodiments, the display panel DP may be bendable, foldable, or rollable. In such cases, the display panel DP and/or a substrate of the display panel DP may include materials having a flexible property.

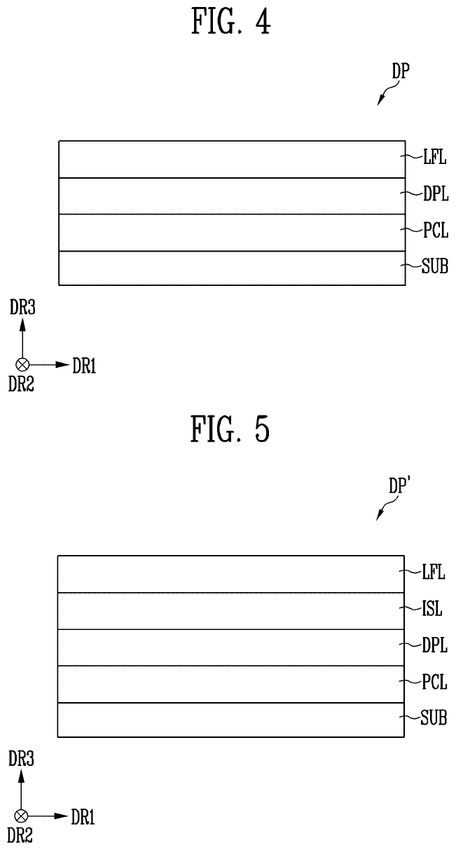

FIG. 4 is a cross-sectional view illustrating an embodiment of the display panel of FIG. 3.

Referring to FIG. 4, the display panel DP may include a substrate SUB, and a pixel circuit layer PCL, a display element layer DPL, and a light functional layer LFL sequentially stacked on the substrate SUB in a third direction DR3 crossing the first and second directions DR1 and DR2.

The substrate SUB may include an insulating material such as glass or resin. For example, the substrate SUB may include a glass substrate. As another example, the substrate SUB may include a polyimide (PI) substrate. As still another example, the substrate SUB may include a silicon wafer substrate formed using a semiconductor process.

In an embodiment, the substrate SUB may include a flexible material that may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL is located on the substrate SUB. The pixel circuit layer PCL may include insulating layers and semiconductor electrodes and conductive electrodes located between the insulating layers. The conductive electrodes of the pixel circuit layer PCL may function as circuit elements, lines, and the like.

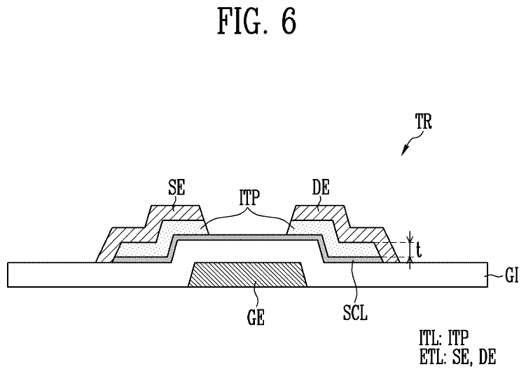

The circuit elements of the pixel circuit layer PCL may include the sub-pixel circuit SPC (refer to FIG. 2) of each of the sub-pixels SP of FIG. 3. In other words, the circuit elements of the pixel circuit layer PCL may be provided as transistors TR (refer to FIG. 6) and one or more capacitors of the sub-pixel circuit SPC.

The lines of the pixel circuit layer PCL may include lines connected to the sub-pixels SP. The lines of the pixel circuit layer PCL may include various signal lines and/or voltage lines necessary to drive the display element layer DPL.

The display element layer DPL is located on the pixel circuit layer PCL. The display element layer DPL may include light emitting elements of the sub-pixels SP.

The light functional layer LFL may be located on the display element layer DPL. The light functional layer LFL may include light conversion patterns having color conversion particles and/or scattering particles. For example, the color conversion particles may include quantum dots. The quantum dots may change a wavelength (or color) of light emitted from the display element layer DPL. The light functional layer LFL may further include light scattering patterns having the scattering particles. In an embodiment, the light conversion patterns and the light scattering patterns may be omitted.

The light functional layer LFL may include a color filter layer including color filters. The color filter may selectively transmit light of a specific wavelength (or a specific color). In an embodiment, the color filter layer may be omitted.

A window for protecting an exposed surface (or an upper surface) of the display panel DP may be provided on the light functional layer LFL. The window may protect the display panel DP from external shock. The window may be coupled to the light functional layer LFL through an optically transparent adhesive (or cohesive) member. The window may have a multi-layer structure selected from a glass substrate, a plastic film, and a plastic substrate. The multi-layer structure may be formed through a continuous process or an adhesion process using an adhesive layer. All or a portion of the window may be flexible.

FIG. 5 is a cross-sectional view illustrating another embodiment of the display panel of FIG. 3.

Referring to FIG. 5, the display panel DP′ may include the substrate SUB, the pixel circuit layer PCL, the display element layer DPL, an input sensing layer ISL, and the light functional layer LFL. The substrate SUB, the pixel circuit layer PCL, the display element layer DPL, and the light functional layer LFL are configured similarly to the substrate SUB, the pixel circuit layer PCL, the display element layer DPL, and the light functional layer LFL described with reference to FIG. 4, respectively. Hereinafter, an overlapping description is omitted.

The input sensing layer ISL may sense a user input on an upper surface (or a display surface) of the display panel DP′. The input sensing layer ISL may include components suitable for sensing an external object such as a user's hand, or a pen. For example, the input sensing layer ISL may include touch electrodes.

FIG. 6 is a cross-sectional view illustrating an embodiment of a transistor included in the pixel circuit layer of FIG. 4 or 5.

Referring to FIG. 6, the transistor TR may include a gate electrode GE, a gate insulating layer GI, a semiconductor layer SCL, an intermediate layer ITL, and an electrode layer ETL.

The gate electrode GE may be located on the substrate SUB of FIG. 5. The gate insulating layer GI may be located on the gate electrode GE while covering the gate electrode GE.

The semiconductor layer SCL may be located on the gate insulating layer GI. The semiconductor layer SCL may overlap the gate electrode GE on the gate insulating layer GI.

In an embodiment, the semiconductor layer SCL may include a material having a layered structure. The semiconductor layer SCL may include transition metal dichalogenides (TMDC). For example, the semiconductor layer SCL may include molybdenum disulfide (MoS₂).

The semiconductor layer SCL may be configured of one layer of molybdenum disulfide. Because the semiconductor layer SCL is configured of one layer of molybdenum disulfide, electron mobility of the semiconductor layer SCL may be improved, and on/off ratio of a current may be improved.

The intermediate layer ITL may be located on the semiconductor layer SCL. The intermediate layer ITL may be in direct contact with the semiconductor layer SCL. The intermediate layer ITL may include interlayer patterns ITP spaced apart from each other.

In an embodiment, the intermediate layer ITL may include a material having a layered structure similarly to the semiconductor layer SCL. In addition, the intermediate layer ITL may include transition metal dichalcogenides TMDC. For example, the intermediate layer ITL may include titanium disulfide (TiS₂). However, embodiments are not limited thereto, and in another embodiment, the intermediate layer ITL may include bismuth (Bi).

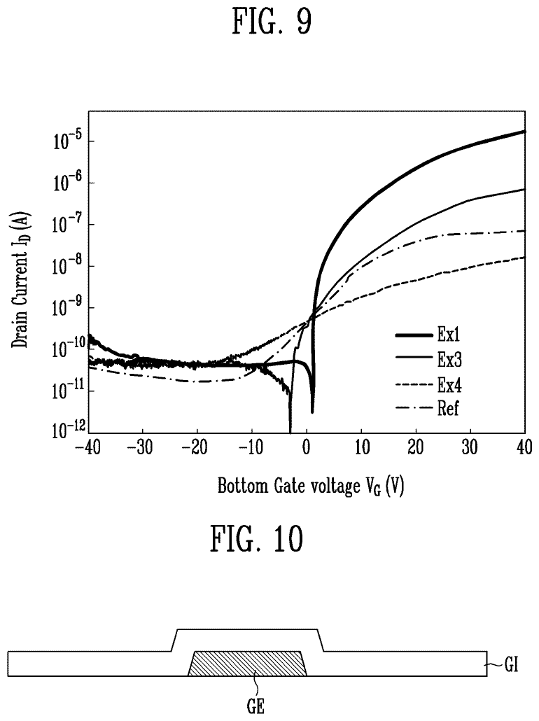

A thickness t of the intermediate layer ITL may be between about 9 nm and about 11 nm. This is described later with reference to FIG. 9.

The electrode layer ETL may be located on the intermediate layer ITL. The electrode layer ETL may include a source electrode SE and a drain electrode DE spaced apart from each other. The source electrode SE and the drain electrode DE may respectively overlap the interlayer patterns ITP.

In an embodiment, the electrode layer ETL may include a metal. For example, the electrode layer ETL may include at least one of gold (Au), silver (Ag), or titanium (Ti).

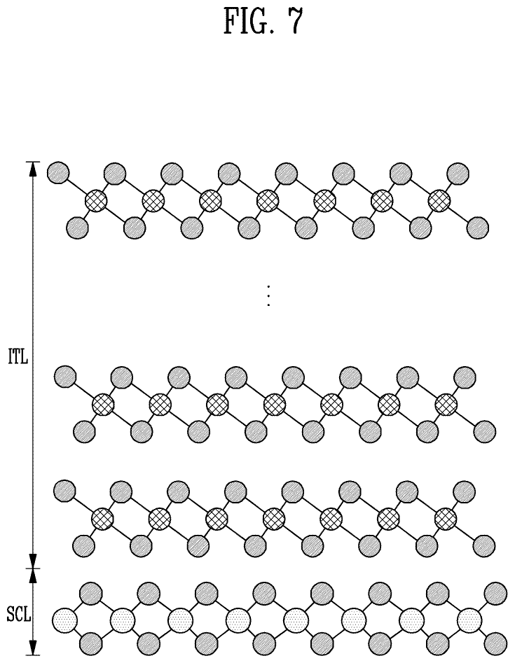

FIG. 7 is an enlarged cross-sectional view of a portion of the semiconductor layer and the intermediate layer of FIG. 6.

Referring to FIG. 7, the semiconductor layer SCL and the intermediate layer ITL may be in direct contact with each other. The semiconductor layer SCL may include molybdenum disulfide, and the intermediate layer ITL may include titanium disulfide. In addition, the semiconductor layer SCL may be configured of one layer of molybdenum disulfide, and the intermediate layer ITL may be configured of multiple layers of titanium disulfide, and may have a thickness of about 9 nm to about 11 nm.

By disposing the titanium disulfide intermediate layer ITL which is in contact with the semiconductor layer SCL, metal-induced gap states (MIGS) of the semiconductor layer SCL may be suppressed. Accordingly, Fermi-level depinning may occur, and a contact resistance between the semiconductor layer SCL and the intermediate layer ITL may be reduced. As the contact resistance is reduced, electron mobility of the transistor may be improved.

In addition, because each of the semiconductor layer SCL and the intermediate layer ITL includes a material having a layered structure and include TMDC, the semiconductor layer SCL and the intermediate layer ITL may include a material of a same series. In addition, titanium disulfide configuring the intermediate layer ITL may be a material having a work function similar to the lowest energy state of a conduction band of molybdenum disulfide configuring the semiconductor layer SCL. Therefore, because compatibility of a material property of titanium disulfide and molybdenum disulfide is high, process compatibility between titanium disulfide and molybdenum disulfide may be secured. Accordingly, because the intermediate layer ITL is easily formed on the semiconductor layer SCL, process efficiency may be improved.

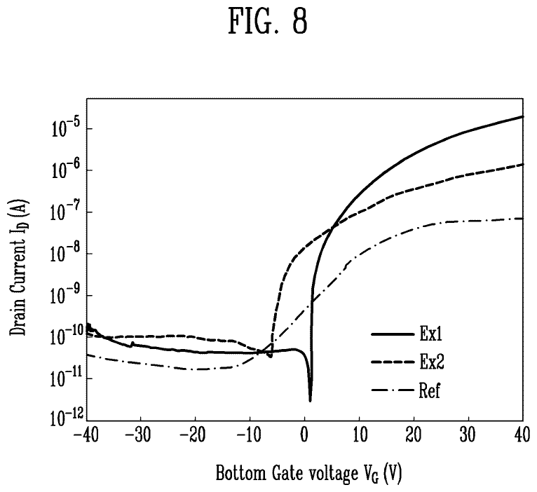

FIG. 8 is a graph illustrating a transfer curve of the transistor shown in FIG. 6. In FIG. 8, an x-axis represents a gate voltage, and a y-axis represents a drain current.

### Comparative Example (Ref), First Embodiment (Ex1), Second Embodiment (Ex2)

A transistor was manufactured under a same condition except for the intermediate layer. The semiconductor layer of each of the comparative example (Ref), the first embodiment (Ex1), and the second embodiment (Ex2) included molybdenum disulfide, and the electrode layer included gold. In addition, a distance between two interlayer patterns included in the intermediate layer is about 4 micrometers, and a length of the semiconductor layer in a longitudinal direction of each of the two interlayer patterns is about 300 micrometers.

The comparative example (Ref) is an example illustrating a case where the intermediate layer is not formed, the first embodiment (Ex1) is an example illustrating a case where the intermediate layer includes titanium disulfide of a thickness of about 10 nm, and the second embodiment (Ex2) is an example illustrating a case where the intermediate layer includes bismuth of a thickness of about 20 nm.

Characteristics of the transistor according to the comparative example (Ref), the first embodiment (Ex1), and the second embodiment (Ex2) are as shown in Table 1 below.

TABLE 1

| | Vₜₕ | Off current | On/off | Mobility | S.S |
|---|---|---|---|---|---|
| | (V) | (A) | ratio | (cm²/Vs) | (V/dec) |
| First | 1.20 | 3.15 × 10⁻¹² | 6.06 × 10⁶ | 6.55 | 0.71 |
| embodiment | | | | | |
| (Ex1) | | | | | |
| Second | −4.95 | 3.26 × 10⁻¹¹ | 4.40 × 10⁴ | 0.50 | 2.48 |
| embodiment | | | | | |
| (Ex2) | | | | | |
| Comparative | 4.10 | 1.74 × 10⁻¹¹ | 4.28 × 10³ | 0.03 | 3.83 |
| example(Ref) | | | | | |

Referring to Table 1, under the condition described above, a threshold voltage (Vₜₕ), an off current (Off current), a ratio of on/off current (On/off ratio), mobility of an electron (Mobility), and swing (S.S) equal to or less than a threshold voltage according to each of the comparative example (Ref), the first embodiment (Ex1), and the second embodiment (Ex2) were measured.

Referring to FIG. 8 and Table 1, it may be confirmed that the threshold voltage of the transistor according to each of the first embodiment (Ex1) and the second embodiment (Ex2) is less than the threshold voltage of the transistor according to the comparative example (Ref).

It may be confirmed that the ratio of the on/off current of the transistor according to each of the first embodiment (Ex1) and the second embodiment (Ex2) is greater than the ratio of the on/off current of the transistor according to the comparative example (Ref). In addition, it may be confirmed that the ratio of the on/off current of the transistor according to the first embodiment (Ex1) is greater than the ratio of the on/off current of the transistor according to the second embodiment (Ex2).

It may be confirmed that the mobility of the electron of the transistor according to each of the first embodiment (Ex1) and the second embodiment (Ex2) is greater than the mobility of the electron of the transistor according to the comparative example (Ref). In addition, it may be confirmed that the mobility of the electron of the transistor according to the first embodiment (Ex1) is greater than the mobility of the electron of the transistor according to the second embodiment (Ex2).

It may be confirmed that a swing value equal to or less than a threshold voltage of the transistor according to each of the first embodiment (Ex1) and the second embodiment (Ex2) is less than a swing value equal to or less than a threshold voltage of the transistor according to the comparative example (Ref). In addition, it may be confirmed that the swing value equal to or less than the threshold voltage of the transistor according to the first embodiment (Ex1) is less than the swing value equal to or less than the threshold voltage of the transistor according to the second embodiment (Ex2).

Through this, it may be confirmed that performance of the transistor according to each of the first and second embodiments (Ex1 and Ex2) is superior than the comparative example (Ref). Among them, it may be confirmed that the performance of the transistor according to the first embodiment (Ex1) including titanium disulfide is the best. Accordingly, it may be known that disposing the intermediate layer between the semiconductor layer and the electrode layer in the transistor improves the performance of the transistor, and in particular, it may be confirmed that the performance of the transistor is the best in case that the intermediate layer is the TMDC, for example, titanium disulfide.

FIG. 9 is a graph illustrating a transfer curve of the transistor shown in FIG. 6. In FIG. 9, an x-axis represents a gate voltage, and a y-axis represents a drain current.

### Comparative Example (Ref), First Embodiment (Ex1), Third Embodiment (Ex3), Fourth Embodiment (Ex4)

Similarly to FIG. 8, the transistor was manufactured under same conditions except for the intermediate layer. The third embodiment (Ex3) is an embodiment illustrating a case where the intermediate layer includes titanium disulfide of a thickness of about 5 nm, and the fourth embodiment (Ex4) is an embodiment illustrating a case where the intermediate layer includes titanium disulfide of a thickness of about 2 nm.

Characteristics of the transistor according to each of the comparative example (Ref), the first embodiment (Ex1), the third embodiment (Ex3), and the fourth embodiment (Ex4) are as shown in Table 2 below.

TABLE 2

| | Vₜₕ | Off current | On/off | Mobility | S.S |
|---|---|---|---|---|---|
| | (V) | (A) | ratio | (cm²/Vs) | (V/dec) |
| First | 1.20 | 3.15 × 10⁻¹² | 6.06 × 10⁶ | 6.55 | 0.71 |
| embodiment | | | | | |
| (Ex1) | | | | | |
| Third | −2.10 | 5.98 × 10⁻¹³ | 1.31 × 10⁶ | 0.27 | 1.01 |
| embodiment | | | | | |
| (Ex3) | | | | | |
| Fourth | −9.60 | 3.67 × 10⁻¹¹ | 4.28 × 10² | 0.01 | 4.68 |
| embodiment | | | | | |
| (Ex4) | | | | | |
| Comparative | 4.10 | 1.74 × 10⁻¹¹ | 4.28 × 10³ | 0.03 | 3.83 |
| example(Ref) | | | | | |

Referring to Table 2, under the condition described above, a threshold voltage (Vₜₕ), an off current (Off current), a ratio of on/off current (On/off ratio), mobility of an electron (Mobility), and swing (S.S) equal to or less than a threshold voltage according to each of the comparative example (Ref), the first embodiment (Ex1), the third embodiment (Ex3), and the fourth embodiment (Ex4) were measured.

Referring to FIG. 9 and Table 2, it may be confirmed that among the first, third, and fourth embodiments (Ex1, Ex3, and Ex4), the ratio of the on/off current of the transistor according to the first embodiment (Ex1) is the greatest, the mobility of the electron is the greatest, and a swing value equal to or less than a threshold voltage is the least. That is, it may be confirmed that among the first, third, and fourth embodiments (Ex1, Ex3, and Ex4), performance of the transistor according to the first embodiment (Ex1) is the best.

Through this, it may be confirmed that the performance of the transistor varies according to a thickness of the intermediate layer even though the intermediate layer includes a same material. That is, it may be confirmed that the performance of the transistor improves as the thickness of the intermediate layer becomes thicker. However, because the intermediate layer is formed by the atomic layer deposition process described later, a process time may increase in case that the intermediate layer is formed to be about 20 nm or more, and thus process efficiency may be reduced. Accordingly, the thickness of the intermediate layer is preferably between about 9 nm and about 11 nm.

FIGS. 10 to 19 are drawings illustrating a method of manufacturing the transistor of FIG. 6 according to an embodiment.

Referring to FIG. 10, the gate electrode GE may be formed on the substrate SUB (refer to FIG. 4). The gate insulating layer GI may be formed on the gate electrode GE while covering the gate electrode GE.

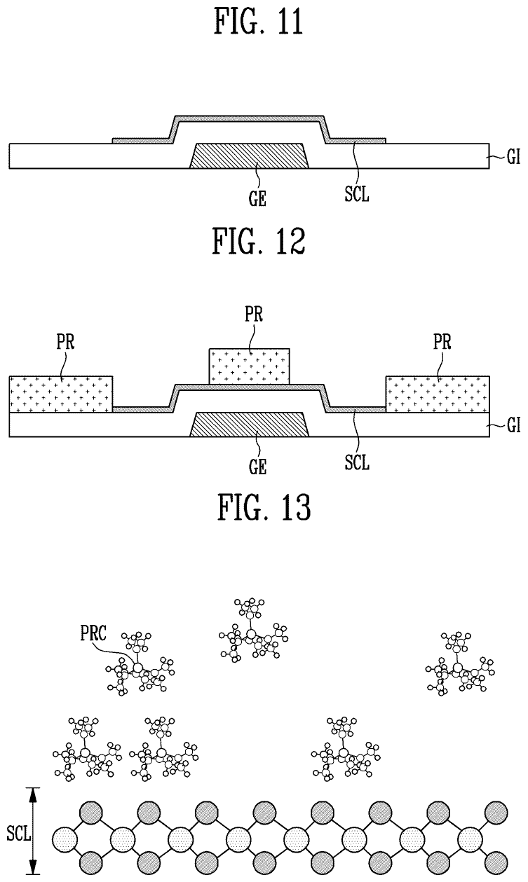

Referring to FIG. 11, the semiconductor layer SCL may be formed on the gate insulating layer GI. The semiconductor layer SCL may be formed to overlap the gate electrode GE. The semiconductor layer SCL may include a material having a layered structure. The semiconductor layer SCL may include TMDC. For example, the semiconductor layer SCL may include molybdenum disulfide.

Referring to FIG. 12, photoresist patterns PR may be formed on the semiconductor layer SCL. The photoresist patterns PR may be formed without overlapping a portion where the interlayer patterns ITP, the source electrode SE, and the drain electrode DE are to be located later. That is, after a photoresist layer may be entirely formed on the gate insulating layer GI and the semiconductor layer SCL, and then portions of the photoresist layer formed in a portion where the interlayer patterns ITP, the source electrode SE, and the drain electrode DE are to be located may be removed. Accordingly, the photoresist patterns PR spaced apart from each other may be formed.

Referring to FIGS. 13 to 17, the intermediate layer ITL may be entirely formed on the semiconductor layer SCL and the photoresist patterns PR. The intermediate layer ITL may be formed by an atomic layer deposition (ALD).

Referring to FIG. 13, a precursor PRC may be injected into a surface of each of the semiconductor layer SCL and the photoresist patterns PR. The injected precursor PRC may be adsorbed onto the surface of each of the semiconductor layer SCL and the photoresist patterns PR. The precursor PRC is adsorbed onto the surface of each of the semiconductor layer SCL and the photoresist patterns PR means both of a meaning that the precursor PRC reacts and binds with the surface of each of the semiconductor layer SCL and the photoresist patterns PR and a meaning that the precursor PRC is located on the surface of each of the semiconductor layer SCL and the photoresist patterns PR without reacting with the surface of each of the semiconductor layer SCL and the photoresist patterns PR.

The precursor PRC may include tetrakis(dimethylamino)titanium (TDMAT).

Referring to FIG. 14, the injected precursor PRC may be adsorbed on the surface of each of the semiconductor layer SCL and the photoresist patterns PR to form one layer, and then a non-adsorbed precursor PRC may be removed. Accordingly, one layer of precursor PRC may be formed on the semiconductor layer SCL.

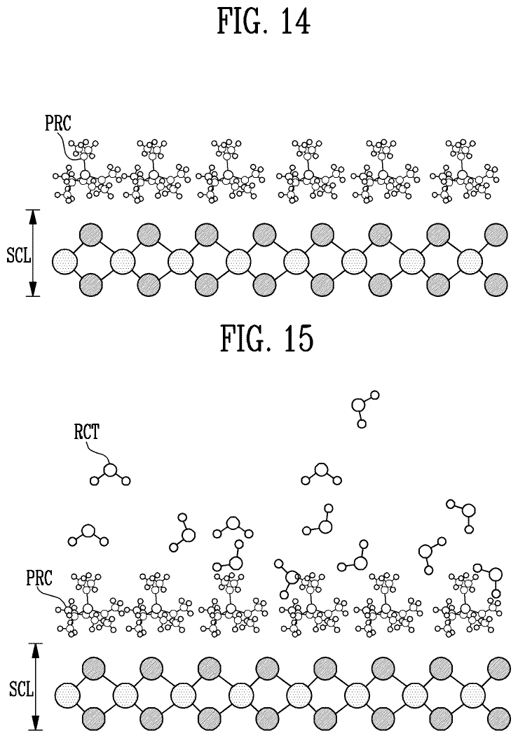

Referring to FIG. 15, a reactant RCT may be injected on the surface of each of the semiconductor layer SCL and the photoresist patterns PR. The injected reactant RCT may react with the precursor PRC adsorbed on the surface of each of the semiconductor layer SCL and the photoresist patterns PR. The reactant RCT may include hydrogen sulfide (H₂S). Therefore, the reactant RCT and the precursor PRC may react to form titanium disulfide.

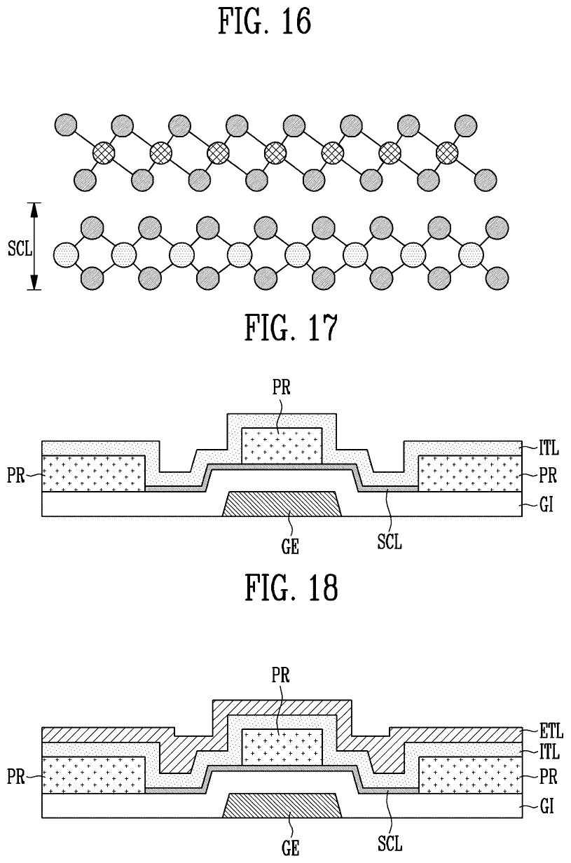

Referring to FIG. 16, the reactant RCT may react with the precursor PRC to form one layer of titanium disulfide. Thereafter, the remaining reactant RCT may be removed. Therefore, one layer of titanium disulfide may be formed on the semiconductor layer SCL.

Referring to FIG. 17, the injection and removal processes of the precursor PRC of FIGS. 13 to 16 and the injection and removal processes of the reactant RCT may be repeated to form multiple layers of titanium disulfide (refer to FIG. 7). Accordingly, the intermediate layer ITL including titanium disulfide having a layered structure may be formed.

Referring to FIG. 18, the electrode layer ETL may be entirely formed on the intermediate layer ITL. The electrode layer ETL may be formed by depositing a metal. For example, the electrode layer ETL may include gold.

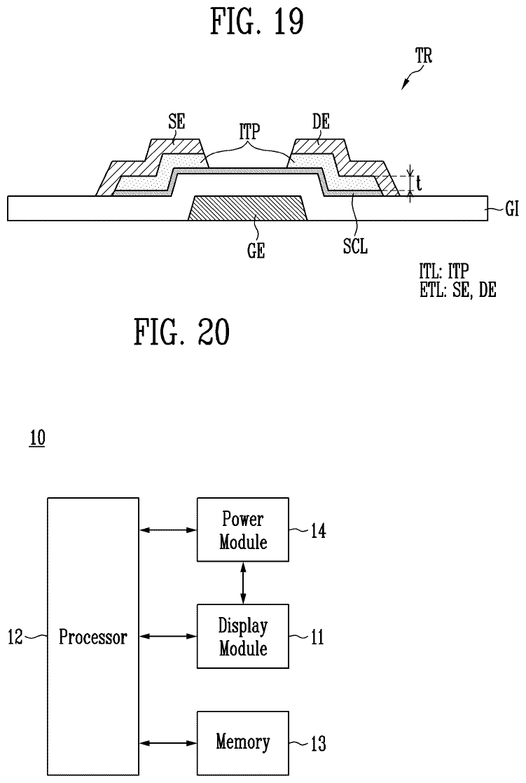

Referring to FIG. 19, the photoresist patterns PR may be removed. That is, the photoresist patterns PR may be removed through a lift-off process. Accordingly, a portion of each of the electrode layer ETL and the intermediate layer ITL on the photoresist patterns PR may be removed when removing the photoresist patterns. Accordingly, only a portion of the intermediate layer ITL that does not overlap the photoresist patterns PR may remain, and thus the interlayer patterns ITP spaced apart from each other may be formed. In addition, only a portion of the electrode layer ETL that does not overlap the photoresist patterns PR may remain, and thus the source electrode SE and the drain electrode DE respectively overlapping the interlayer patterns ITP and spaced apart from each other may be formed.

In an embodiment, because the intermediate layer ITL is formed by the ALD, defect-induced gap states (DIGS) of the semiconductor layer SCL may be suppressed. That is, because the intermediate layer ITL is formed by the ALD, a material forming the intermediate layer ITL during an intermediate layer formation process is prevented from causing damage to the surface of the semiconductor layer SCL or diffusing into the semiconductor layer SCL, thereby minimizing a defect on the surface of the semiconductor layer SCL. Accordingly, Fermi-level depinning may occur, the contact resistance between the semiconductor layer SCL and the intermediate layer ITL may be reduced, and thus the electron mobility of the transistor TR may be improved.

A display device according to an embodiment is applicable to various types of electronic devices. In an embodiment, an electronic device includes the above-described display device and may further include other modules or devices having additional functions in addition to the display device.

FIG. 20 is a block diagram of an electronic device according to an embodiment. Referring to FIG. 20, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

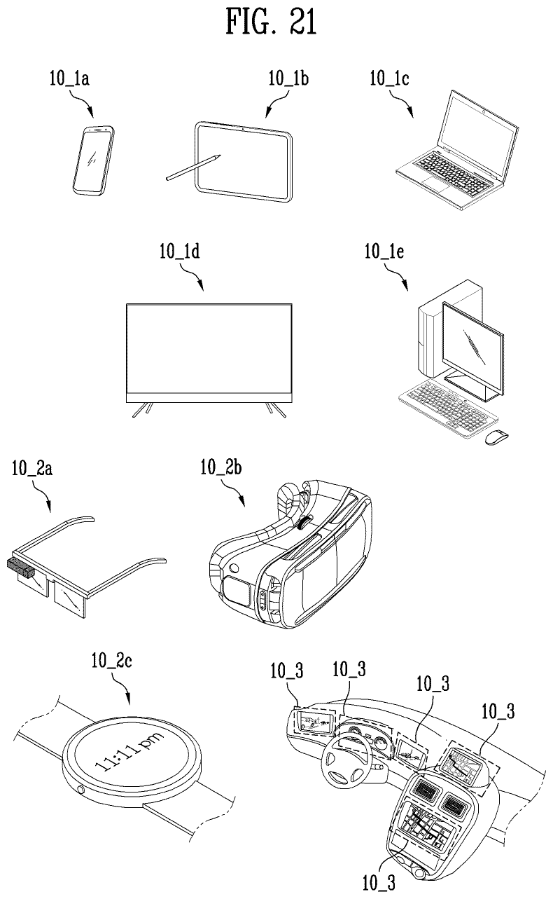

FIG. 21 shows schematic views of various embodiments of an electronic device.

Referring to FIG. 21, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Although the technical spirit of the disclosure has been described in detail in accordance with the above-described embodiments, it should be noted that the above-described embodiments are for the purpose of description and not of limitation. Those skilled in the art can understand that various modifications are possible within the scope of the technical spirit of the disclosure.

The scope of the disclosure is not limited to the details described in the detailed description of the specification, but should be defined by the claims. It is to be construed that all changes or modifications derived from the meaning and scope of the claims and equivalent concepts thereof are included in the scope of the disclosure.

What is claimed is:

1. A transistor comprising:
a gate electrode;
a semiconductor layer disposed on the gate electrode;
a gate insulating layer disposed between the gate electrode and the semiconductor layer;
an electrode layer including a source electrode and a drain electrode spaced apart from each other on the semiconductor layer; and
an intermediate layer disposed between the semiconductor layer and the electrode layer, and including interlayer patterns respectively overlapping the source electrode and the drain electrode.

2. The transistor according to claim 1, wherein each of the semiconductor layer and the intermediate layer includes a material having a layered structure.

3. The transistor according to claim 1, wherein each of the semiconductor layer and the intermediate layer includes transition metal dichalogenides (TMDC).

4. The transistor according to claim 3, wherein the semiconductor layer includes molybdenum disulfide (MoS₂).

5. The transistor according to claim 4, wherein the semiconductor layer includes one layer of molybdenum disulfide.

6. The transistor according to claim 3, wherein the intermediate layer includes titanium disulfide (TiS₂).

7. The transistor according to claim 1, wherein a thickness of the intermediate layer is between about 9 nm and about 11 nm.

8. The transistor according to claim 1, wherein the electrode layer includes a metal.

9. A method of manufacturing a transistor, the method comprising:
forming a gate electrode;
forming a gate insulating layer on the gate electrode;
forming a semiconductor layer on the gate insulating layer;
forming an intermediate layer including interlayer patterns spaced apart from each other and an electrode layer including a source electrode and a drain electrode spaced apart from each other and respectively overlapping the interlayer patterns on the semiconductor layer.

10. The method according to claim 9, further comprising:
forming a photoresist pattern on the semiconductor layer after forming the semiconductor layer and before forming the intermediate layer.

11. The method according to claim 10, wherein the forming the intermediate layer is performed by atomic layer deposition (ALD).

12. The method according to claim 11, wherein the forming the intermediate layer comprises:
injecting a precursor into a surface of each of the semiconductor layer and the photoresist pattern;
removing a precursor which is not adsorbed onto the surface of each of the semiconductor layer and the photoresist pattern;
injecting a reactant into the surface of each of the semiconductor layer and the photoresist pattern; and
removing the remaining reactant.

13. The method according to claim 12, wherein the precursor includes tetrakis(dimethylamino)titanium (TDMAT).

14. The method according to claim 12, wherein the reactant includes hydrogen sulfide (H₂S).

15. The method according to claim 12, further comprising:
removing the photoresist pattern after forming the electrode layer,
wherein in removing the photoresist pattern, a portion of each of the electrode layer and the intermediate layer overlapping the photoresist pattern is removed to form the interlayer patterns spaced apart from each other and the source electrode and the drain electrode spaced apart from each other.

16. The method according to claim 9, wherein the semiconductor layer includes molybdenum disulfide.

17. The method according to claim 9, wherein the electrode layer includes metal.

18. An electronic device, comprising:
a processor to provide input image data; and
a display device to display an image based on the input image data,
wherein the display device comprises: a gate electrode;
a semiconductor layer disposed on the gate electrode;
a gate insulating layer disposed between the gate electrode and the semiconductor layer;
an electrode layer including a source electrode and a drain electrode spaced apart from each other on the semiconductor layer; and
an intermediate layer disposed between the semiconductor layer and the electrode layer, and including interlayer patterns respectively overlapping the source electrode and the drain electrode.
